(19) United States
(12) Patent Application Publication
(10) Pub. No.: US 2020/0041901 A1
(43) Pub. Date: Feb. 6, 2020

(54) SEMICONDUCTOR RESIST COMPOSITION, AND METHOD OF FORMING PATTERNS USING THE COMPOSITION

(71) Applicant: Samsung SDI Co., Ltd., Yongin-si (KR)

(72) Inventors: Ran NAMGUNG, Suwon-si (KR); Jaehyun KIM, Suwon-si (KR); Yoong Hee NA, Suwon-si (KR); Kyung Soo MOON, Suwon-si (KR); Hwansung CHEON, Suwon-si (KR); Seungyong CHAE, Suwon-si (KR)

(21) Appl. No.: 16/211,068

(22) Filed: Dec. 5, 2018

(30) Foreign Application Priority Data
Jul. 31, 2018 (KR) 10-2018-0089412

(51) Int. Cl. G03F 7/038; H01L 21/308; G03F 7/20; G03F 7/16; G03F 7/004

(52) U.S. Cl. CPC G03F 7/0382; H01L 21/3086; G03F 7/70033; G03F 7/0042; G03F 7/0045; G03F 7/0384; G03F 7/168

(57) ABSTRACT

This disclosure relates to a semiconductor resist composition including an organometallic compound including a structural unit represented by Chemical Formula 1 and a solvent, and to a method of forming patterns using the composition:

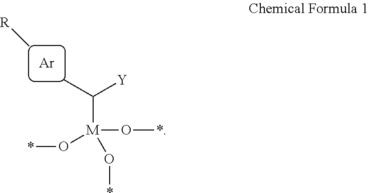

wherein in Chemical Formula 1, carbon bonded with a central metal atom (M) forms a benzylic bond with a ring group having a conjugated structure, such as an aromatic ring group, a heteroaromatic ring group, or a combination thereof.

### CROSS-REFERENCE TO RELATED APPLICATION

This application claims priority to and the benefit of Korean Patent Application No. 10-2018-0089412 filed in the Korean Intellectual Property Office on Jul. 31, 2018, the entire content of which is incorporated herein by reference.

### BACKGROUND

### 1. Field

One or more aspects of embodiments of this disclosure are directed toward a semiconductor resist composition and a method of forming patterns using the composition.

### 2. Description of the Related Art

EUV (extreme ultraviolet) lithography is recently being examined as one essential technology for manufacturing next generation semiconductor devices. The EUV lithography is a pattern-forming technology that uses an EUV ray having a wavelength of about 13.5 nm as an exposure light source. With the help of the EUV lithography, an extremely fine pattern (e.g., a pattern having a width of less than or equal to about 20 nm) may be formed in an exposure process during a manufacture of a semiconductor device.

The extreme ultraviolet (EUV) lithography is realized through the development of compatible photoresists which can be performed at a spatial resolution of less than or equal to about 16 nm. Currently, efforts to satisfy insufficient (e.g., less than desirable) specifications of related chemically amplified (CA) photoresists, such as resolution, photospeed, and feature roughness (e.g., line edge roughness (LER)), for the next generation device are being made.

An intrinsic image blur due to an acid catalyzed reaction in these polymer-type photoresists (e.g., polymer photoresists) may limit a resolution in small feature sizes, which is a known phenomenon in electron beam (e-beam) lithography. The chemically amplified (CA) photoresists are designed for high sensitivity, but since the elemental makeups of related CA photoresists may reduce light absorbance of the photoresists at a wavelength of about 13.5 nm and thus may decrease their sensitivity, the chemically amplified (CA) photoresists may partially have more difficulties under an EUV exposure (e.g., may not be suitable for an EUV exposure).

In addition, the CA photoresists may have difficulties in the small feature sizes (e.g., may not be suitable for manufacturing small feature sizes) due to roughness issues, for example, line edge roughness (LER) of the CA photoresists experimentally turns out to be increased, as a photospeed is decreased partially due to an essence of acid catalyst processes. Accordingly, a novel high performance photoresist is desired in a semiconductor industry to mitigate these defects and problems of the CA photoresists.

### SUMMARY

One or more aspects of embodiments of the present disclosure are directed toward a semiconductor resist composition having improved etch resistance, sensitivity, and pattern-forming capability.

One or more aspects of embodiments of the present disclosure are directed toward a method of forming patterns using the semiconductor resist composition.

A semiconductor resist composition according to an embodiment includes an organometallic compound having a structural unit represented by Chemical Formula 1 and a solvent:

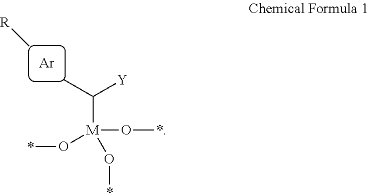

In Chemical Formula 1,

M may be selected from indium (In), tin (Sn), antimony (Sb), tellurium (Te), thallium (Tl), lead (Pb), bismuth (Bi), and polonium (Po),

Ar may be a substituted or unsubstituted C6 to C30 aromatic ring group, a substituted or unsubstituted C4 to C30 heteroaromatic ring group, or a combination thereof,

R may be selected from hydrogen, deuterium, a halogen, a substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),

R^{a} to R^{c} may each independently be selected from hydrogen, deuterium, a substituted or unsubstituted C1 to C20 alkyl group, a substituted or unsubstituted C3 to C20 cycloalkyl group, and a substituted or unsubstituted C6 to C30 aryl group,

adjacent R's may be fused to form a ring,

Y may be selected from hydrogen, deuterium, a halogen, a substituted or unsubstituted C1 to C20 alkyl group, a substituted or unsubstituted C3 to C20 cycloalkyl group, and a substituted or unsubstituted C6 to C30 aryl group, and

“*” is a linking point.

A method of forming patterns according to another embodiment includes coating the semiconductor resist composition on an etching subject layer to form a photoresist layer, patterning the photoresist layer to form a photoresist pattern, and etching the etching subject layer using the photoresist pattern as an etching mask.

The semiconductor resist composition according to embodiments of the present disclosure has relatively improved (e.g., suitable) sensitivity and pattern-forming capability and thus may provide a photoresist pattern having improved sensitivity and a high aspect ratio without a pattern collapse.

### BRIEF DESCRIPTION OF THE DRAWINGS

FIGS. 1-5 are cross-sectional views of acts of a method of forming patterns using a semiconductor resist composition according to an embodiment.

FIG. 6 shows a scanning electron microscope (SEM) image of a pattern formed using a semiconductor resist composition according to an embodiment.

### DETAILED DESCRIPTION

Hereinafter, the example embodiments of the present invention will be described in more detail, by referring to the accompanying drawings. However, in the description of the present disclosure, descriptions of functions or components that are well known in the art will not be provided.

In the present disclosure and drawings, the same reference numerals refer to the same or like components throughout. In addition, since the size and the thickness of each component shown in the drawings are optionally represented for convenience of the description, the present disclosure is not limited to the provided illustrations. For example, in the drawings, the thickness of layers, films, panels, regions, etc., may be exaggerated for clarity, and the thickness of a part of layers or regions, etc., may be exaggerated for clarity.

It will be understood that when an element such as a layer, film, region, or substrate is referred to as being “on” another element, it can be directly on the other element or intervening elements may also be present.

In this disclosure, “substituted” may refer to replacement of a hydrogen atom of any given compound or functional group by at least one selected from deuterium, a halogen, a hydroxy group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, and a cyano group. “Unsubstituted” may refer to any given compound or functional group in which a hydrogen atom is not replaced by another substituent.

As used herein, when a definition is not otherwise provided, “hetero” may refer to the inclusion of 1 to 3 heteroatoms selected from N, O, and S.

As used herein, when a definition is not otherwise provided, “alkyl group” may refer to a linear or branched aliphatic hydrocarbon group. The alkyl group may be “a saturated alkyl group” without any double bond or triple bond.

The alkyl group may be, for example, a C1 to C20 alkyl group. More specifically, the alkyl group may be a C1 to C10 alkyl group or a C1 to C6 alkyl group. For example, a C1 to C4 alkyl group may have one to four carbon atoms in the alkyl chain, and may be selected from methyl, ethyl, propyl, iso-propyl, n-butyl, iso-butyl, sec-butyl, and t-butyl.

Non-limiting examples of the alkyl group may refer to a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and the like.

As used herein, when a definition is not otherwise provided, “a cycloalkyl group” may refer to a monovalent cyclic aliphatic hydrocarbon group.

As used herein, “an aryl group” may refer to a cyclic aromatic group in which all ring-forming atoms have a p-orbital and these p-orbitals are conjugated. The aryl group may be a monocyclic or fused ring polycyclic functional group (i.e., a group having rings sharing adjacent pairs of carbon atoms).

As used herein, “aromatic ring group” may refer to a group having one or more carbocyclic aromatic rings that are fused or coupled to each other.

As used herein, “heteroaromatic ring group” may refer to a group having one or more heterocyclic aromatic rings that are fused or coupled to each other.

As used herein, “a linking point” may refer to a binding site.

A semiconductor resist composition according to an embodiment of the present invention may include an organometallic compound and a solvent.

The organometallic compound may include a structural unit represented by Chemical Formula 1:

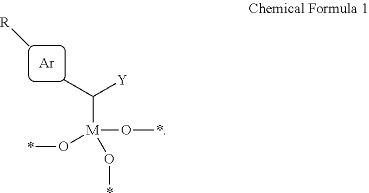

In Chemical Formula 1,

M may be selected from indium (In), tin (Sn), antimony (Sb), tellurium (Te), thallium (Tl), lead (Pb), bismuth (Bi), and polonium (Po),

Ar may be a substituted or unsubstituted C6 to C30 aromatic ring group, a substituted or unsubstituted C4 to C30 heteroaromatic ring group, or a combination thereof,

R may be selected from hydrogen, deuterium, a halogen, a substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),

R^{a} to R^{c} may each independently be selected from hydrogen, deuterium, a substituted or unsubstituted C1 to C20 alkyl group, a substituted or unsubstituted C3 to C20 cycloalkyl group, and a substituted or unsubstituted C6 to C30 aryl group,

adjacent R's may be fused to form a ring,

Y may be selected from hydrogen, deuterium, a halogen, a substituted or unsubstituted C1 to C20 alkyl group, a substituted or unsubstituted C3 to C20 cycloalkyl group, and a substituted or unsubstituted C6 to C30 aryl group, and

“*” is a linking point.

For example, M may be selected from indium (In), tin (Sn), and antimony (Sb). For example, M may be tin (Sn). When M is tin (Sn), the organometallic compound including the structural unit represented by Chemical Formula 1 is an organic tin compound. Because tin may strongly absorb extreme ultraviolet (UV) ray at about 13.5 nm, the organic tin compound according to the present embodiments may have excellent sensitivity to light having high energy. Accordingly, the organic tin compound according to the present embodiments may show improved stability and sensitivity compared with related organic and/or inorganic resists.

In an embodiment, Ar may be an aromatic ring group, a heteroaromatic ring group (e.g., an aromatic heterocyclic group), or a combination thereof, and Ar may be combined with carbon that is bonded with a central metal atom of Chemical Formula 1. The Ar group may reduce bond-dissociation energy of the carbon bonded with the central metal atom during the exposure to an extreme ultraviolet (UV) ray and thus may show excellent sensitivity compared with a compound having an aliphatic cyclic group or an aliphatic hydrocarbon group having no conjugated structure.

The total number of aromatic rings or heteroaromatic rings in Ar may vary. For example, the total number of aromatic rings or heteroaromatic rings in Ar may be about 1 to about 10, for example, about 1 to about 8, about 1 to about 6, about 1 to about 5, or about 1 to about 4.

In some embodiments, Ar may be represented by Chemical Formula 1-1:

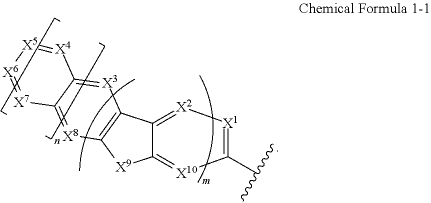

In Chemical Formula 1-1,

X¹ to X⁸ and X¹⁰ may each independently be —C(R^{d})(R^{e})— or —N(R^{f})—,

X⁹ may be selected from —O—, —S—, and —C(R^{g})(R^{h})—,

R^{d}, R^{e}, R^{f}, R^{g}, and R^{h} may each independently be selected from hydrogen, deuterium, a substituted or unsubstituted C1 to C20 alkyl group, a substituted or unsubstituted C3 to C20 cycloalkyl group, and a substituted or unsubstituted C6 to C30 aryl group,

adjacent R^{d}, R^{e}, R^{f}, R^{g}, and R^{h} may respectively be fused to form a ring, and

n and m may each independently be an integer ranging from 0 to 10.

In an embodiment, Ar may include or consist of one or more substituted or unsubstituted aromatic ring groups. For example, Ar may include at least one of the structural units of Group I:

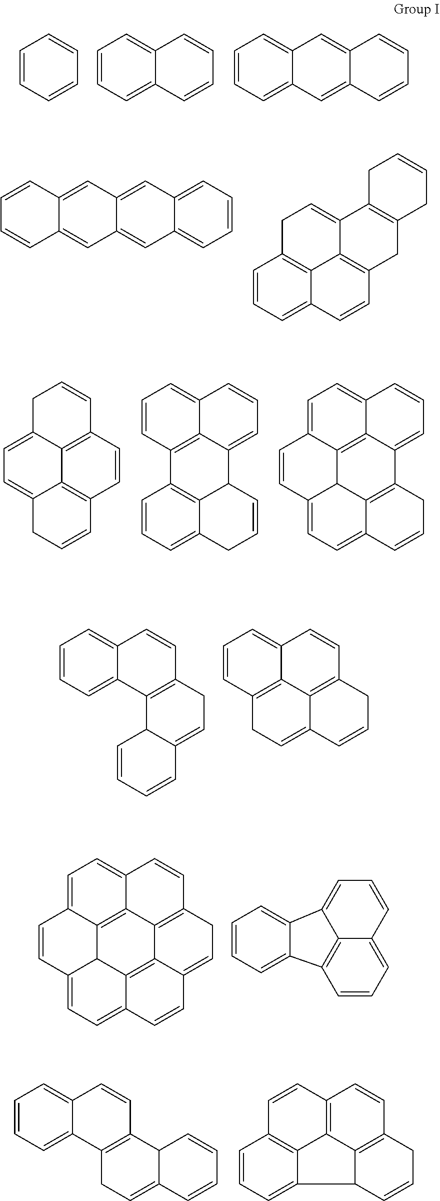

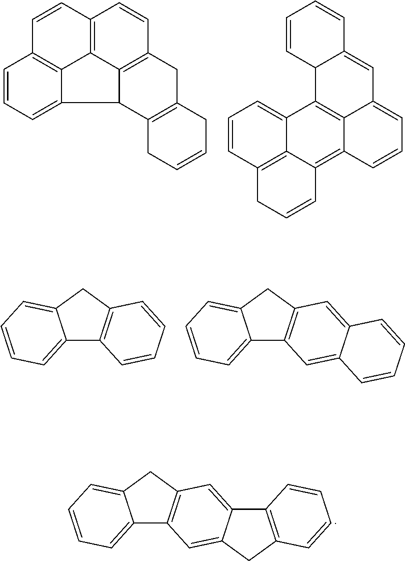

In one or more embodiments, the organometallic compound may include a structural unit represented by Chemical Formula 2:

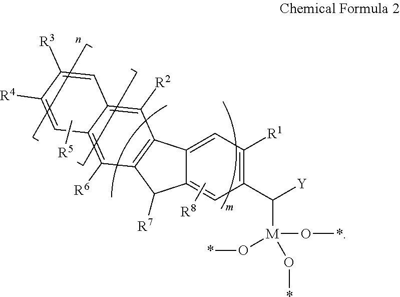

In Chemical Formula 2,

M may be selected from indium (In), tin (Sn), and antimony (Sb),

R¹ to R⁸ may each independently be selected from hydrogen, deuterium, a halogen, a substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),

R^{a} to R^{c} may each independently be selected from hydrogen, deuterium, a substituted or unsubstituted C1 to C20 alkyl group, a substituted or unsubstituted C3 to C20 cycloalkyl group, and a substituted or unsubstituted C6 to C30 aryl group,

adjacent R¹ to R⁸ may be fused to form a ring,

Y may be selected from hydrogen, deuterium, a halogen, a substituted or unsubstituted substituted or unsubstituted C1 to C20 alkyl group, a substituted or unsubstituted C3 to C20 cycloalkyl group, and a substituted or unsubstituted C6 to C30 aryl group, and

“*” is a linking point.

In some embodiments, the organometallic compound may include at least one of structural units represented by Chemical Formulae 3 to 6:

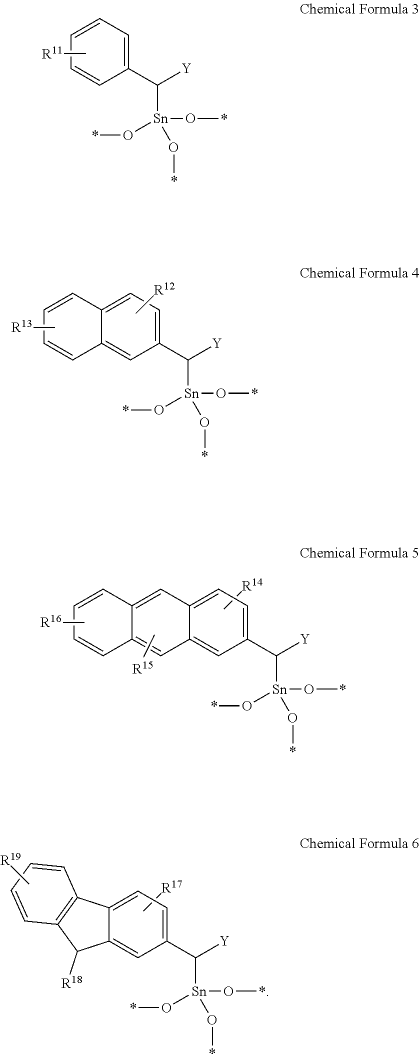

In Chemical Formula 3 to Chemical Formula 6,

R¹¹ to R¹⁹ may each independently be selected from hydrogen, deuterium, a halogen, a substituted or unsubstituted substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),

R^{a} to R^{c} may each independently be selected from hydrogen, deuterium, a substituted or unsubstituted C1 to C20 alkyl group, a substituted or unsubstituted C3 to C20 cycloalkyl group, and a substituted or unsubstituted C6 to C30 aryl group,

adjacent R¹¹ to R¹⁹ may be respectively fused to form a ring,

Y may be selected from hydrogen, deuterium, a halogen, a substituted or unsubstituted substituted or unsubstituted C1 to C20 alkyl group, a substituted or unsubstituted C3 to C20 cycloalkyl group, and a substituted or unsubstituted C6 to C30 aryl group, and

“*” is a linking point.

A related inorganic resist (e.g., a metal oxide compound) may use a mixture of sulfuric acid having high corrosiveness and hydrogen peroxide, and thus may be difficult to handle and may have insufficient storage-stability. In addition, it may be relatively difficult to structurally change such related inorganic resist for performance improvement as a composite mixture, and thus a developing solution having a high concentration should be utilized.

In contrast, the organometallic compound according to an embodiment of the present disclosure includes carbon bonded with a central metal atom, as in a structural unit represented by Chemical Formula 1, that forms a benzylic bond with a ring group having a conjugated structure (such as an aromatic ring group, a heteroaromatic ring group, or a combination thereof, for example, a condensed polycyclic aryl group). The ring group having a conjugated structure is a ligand to the central metal atom and it aids in the solubility of the organometallic compound in an organic solvent. Accordingly, the organometallic compound according to an embodiment shows relatively excellent (e.g., suitable) solubility in an organic solvent and storage stability and may easily form a pattern with a developing solution having a low concentration.

In addition, the organometallic compound according to an embodiment may reduce bond-dissociation energy during the exposure to extreme ultraviolet (UV) light between the central metal atom and the carbon attached thereto, due to the presence of a benzylic bond between the carbon and the ring group having a conjugated structure.

Accordingly, a semiconductor resist composition including the organometallic compound shows excellent (e.g., suitable) sensitivity compared with a composition including an aliphatic cyclic group having no benzyl group, an aliphatic hydrocarbon group, or a simple conjugated structure combined with carbon bonded with a central metal atom. For example, when the composition of the present embodiments is formed into a pattern, the pattern has a high aspect ratio without (or with a very low) risk of collapse.

In the semiconductor resist composition according to an embodiment, the organometallic compound including the structural unit represented by Chemical Formula 1 may be included in an amount of about 0.01 wt % to about 10 wt % based on a total weight of the composition. Within these ranges, storage-stability is improved and a thin layer (e.g., a thin film) may be easily formed.

The solvent of the semiconductor resist composition according to the embodiment may be an organic solvent, and may include, for example, aromatic compounds (e.g., xylene, toluene, and/or the like), alcohols (e.g., 4-methyl-2-pentenol, 4-methyl-2-propanol, 1-butanol, methanol, isopropyl alcohol, 1-propanol, and/or the like), ethers (e.g., anisole, tetrahydrofuran, and/or the like), ester compounds (e.g., n-butyl acetate, propylene glycol monomethyl ether acetate, ethyl acetate, ethyl lactate, and/or the like), ketones (e.g., methyl ethyl ketone, 2-heptanone, and/or the like), and combinations thereof, but is not limited thereto. For example, in an embodiment, as the solvent, ethyl lactate may be used.

In an example embodiment, the semiconductor resist composition according to the embodiment may further include a photoacid generator, a binder resin, a photopolymerizable monomer, a photopolymerization initiator, a surfactant, a cross-linking agent, a leveling agent, other suitable additives, and/or the like, in addition to the organometallic compound and the solvent. In one embodiment, the photopolymerization initiator is not included. Here, the organometallic compound of the semiconductor resist composition can be cured without the use of the photopolymerization initiator.

The photoacid generator (PAG) in the semiconductor resist composition according to an embodiment may be a material that is decomposed by light to generate acid and it may be used for chemical amplification for improving photosensitivity. The photoacid generator according to an embodiment may include at least one of a diazosulfone-based compound and a triphenylsulfone-based compound.

The photoacid generator may be included in an amount of about 0.1 parts by weight to about 20 parts by weight, for example about 0.5 parts by weight to about 15 parts by weight, or for example about 3 parts by weight to about 10 parts by weight based on 100 parts by weight of the semiconductor composition. When the photoacid generator is included within the amount ranges, development of the resin composition at the exposure part may be easily performed.

The binder resin may include an acryl-based binder resin.

The acryl-based binder resin may be a copolymer of a first ethylenic unsaturated monomer and a second ethylenic unsaturated monomer that is copolymerizable therewith, and may be a resin including at least one acryl-based repeating unit.

The first ethylenic unsaturated monomer may be an ethylenic unsaturated monomer including at least one carboxyl group and non-limiting examples thereof may include acrylic acid, methacrylic acid, maleic acid, itaconic acid, fumaric acid, and combinations thereof.

Non-limiting examples of the second ethylenic unsaturated monomer may include an aromatic vinyl compound (such as styrene, α-methylstyrene, vinyltoluene, vinylbenzylmethylether, and/or the like); an unsaturated carboxylate ester compound (such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, and/or the like); an unsaturated carboxylic acid amino alkyl ester compound (such as 2-aminoethyl(meth)acrylate, 2-dimethylaminoethyl(meth)acrylate, and/or the like); a carboxylic acid vinyl ester compound (such as vinyl acetate, vinyl benzoate, and/or the like); an unsaturated carboxylic acid glycidyl ester compound (such as glycidyl(meth)acrylate, and/or the like); a vinyl cyanide compound (such as (meth)acrylonitrile, and/or the like); and an unsaturated amide compound (such as (meth)acrylamide, and/or the like); and any of these compounds may be used alone or as a mixture of two or more.

Non-limiting examples of the acryl-based binder resin may include polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, and a (meth)acrylic acid/benzylmethacrylate/styrene/2-hydroxyethylmethacrylate copolymer, and any of these compounds may be used alone or as a mixture of two or more.

The binder resin may be included in an amount of about 1 wt % to about 20 wt %, for example about 3 wt % to about 15 wt % based on a total amount of semiconductor resist composition. When the binder resin is included within these ranges, excellent (or suitable) sensitivity, film residue ratios, developability, resolution, and pattern linearity may be obtained.

The photopolymerizable monomer may be mono-functional or multi-functional ester of (meth)acrylic acid including at least one ethylenic unsaturated double bond.

The photopolymerizable monomer may facilitate sufficient polymerization during exposure in a pattern-forming process due to the ethylenic unsaturated double bond and may form a pattern having excellent (or suitable) heat resistance, light resistance, and chemical resistance.

Non-limiting examples of the photopolymerizable monomer may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

The photopolymerizable monomer may be treated with acid anhydride to improve developability.

The photopolymerizable monomer may be included in an amount of about 1 wt % to about 20 wt %, for example about 1 wt % to about 15 wt % based on a total amount of semiconductor resist composition. When the photopolymerizable monomer is included within these ranges, the photopolymerizable monomer is sufficiently cured during exposure in a pattern-forming process and thus reliability is improved and heat resistance, light resistance, chemical resistance, resolution and a close contacting property of the resulting pattern may be improved.

The photopolymerization initiator may be any suitable initiator for a semiconductor resist composition and may be, for example, an acetophenone-based compound, a benzophenone-based compound, a thioxanthone-based compound, a benzoin-based compound, a triazine-based compound, an oxime-based compound, an aminoketone-based compound, and/or the like.

The photopolymerization initiator may include a carbazole-based compound, a diketone-based compound, a sulfonium borate-based compound, a diazo-based compound, an imidazole-based compound, a biimidazole-based compound, and/or the like, in addition, or in the alternative, to the compounds recited above.

The photopolymerization initiator may be used with a photosensitizer capable of causing a chemical reaction by absorbing light and becoming excited and then, transferring its energy. Examples of the photosensitizer may include tetraethylene glycol bis-3-mercapto propionate, pentaerythritol tetrakis-3-mercapto propionate, dipentaerythritol tetrakis-3-mercapto propionate, and the like, without limitation.

The photopolymerization initiator may be included in an amount of about 0.1 wt % to about 5 wt %, for example about 0.3 wt % to about 3 wt % based on a total amount of the semiconductor resist composition. When the photopolymerization initiator is included within these ranges, excellent (or suitable) reliability may be secured due to sufficient (or suitable) curing during the exposure in a pattern-forming process. Accordingly, the resulting pattern may have excellent (or suitable) heat resistance, light resistance, chemical resistance, resolution, and a close contacting property, and transmittance may be prevented or reduced from deterioration due to a non-reaction initiator.

The surfactant may include, for example, an alkylbenzenesulfonate salt, an alkylpyridinium salt, polyethylene glycol, a quaternary ammonium salt, and/or the like, but is not limited thereto.

For example, the semiconductor resist composition may include one or more additives of malonic acid, 3-amino-1,2-propanediol, a leveling agent, a radical polymerization initiator and/or a combination thereof, in order to prevent or reduce the occurrence of stains or spots during the coating, to adjust leveling, and/or to prevent or reduce the occurrence of pattern residue due to non-development. A use amount of the additives may be controlled depending on desired properties.

In addition, the semiconductor resist composition may further include a silane coupling agent as an adherence enhancer in order to improve a close-contacting force with the substrate (e.g., improve adherence of the semiconductor resist composition to the substrate). The silane coupling agent may be, for example, a silane compound including a carbon-carbon unsaturated bond (such as vinyltrimethoxysilane, vinyltriethoxysilane, vinyl trichlorosilane, and/or vinyltris(β-methoxyethoxy)silane), 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane, trimethoxy[3-(phenylamino)propyl]silane, and/or the like, but is not limited thereto.

The semiconductor resist composition may be formed into a pattern having a high aspect ratio without the risk (or with a substantially low risk) of a collapse. For example, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, or about 5 nm to about 20 nm, the semiconductor resist composition may be used for a photoresist process using light in a wavelength ranging from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor resist composition according to an embodiment may be used to realize extreme ultraviolet (UV) lithography using an EUV light source of a wavelength of about 13.5 nm.

According to another embodiment, a method of forming patterns using the semiconductor resist composition is provided. For example, the manufactured pattern may be a photoresist pattern.

The method of forming patterns according to an embodiment includes providing an etching subject layer on a substrate, coating the semiconductor resist composition on the etching subject layer to form a photoresist layer, patterning the photoresist layer to form a photoresist pattern, and etching the etching subject layer using the photoresist pattern as an etching mask.

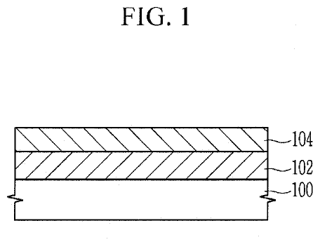

Hereinafter, a method of forming patterns using the semiconductor resist composition is described referring to FIGS. 1-5. FIGS. 1-5 are cross-sectional views of acts of a method of forming patterns using a semiconductor resist composition according to an embodiment.

Referring to FIG. 1, a subject for etching is prepared. The etching subject may be a thin layer 102 (e.g., a thin film) formed (or provided) on a semiconductor substrate 100. Hereinafter, for ease of description, the etching subject will be limited to the thin layer 102. An entire surface of the thin layer 102 is washed to remove impurities and the like remaining thereon. The thin layer 102 may be for example a silicon nitride layer, a polysilicon layer, and/or a silicon oxide layer, without limitation.

Subsequently, a resist underlayer composition for forming a resist underlayer 104 is spin-coated on the surface of the washed thin layer 102. However, the embodiment is not limited thereto, and any suitable coating method may be used.

Hereinafter, the present description will refer to the coating of the resist underlayer, without reference to the specific coating method used.

Then, the coated composition is dried and baked to form a resist underlayer 104 on the thin layer 102. The baking may be performed at about 100° C. to about 500° C., for example, about 100° C. to about 300° C.

The resist underlayer 104 is formed between the substrate 100 and a photoresist layer 106 and may prevent or reduce non-uniformity of a photoresist line width and improve pattern-forming capability when a ray reflected from the interface between the substrate 100 and the photoresist layer 106, or a hardmask between the layers, is scattered into an unintended photoresist region.

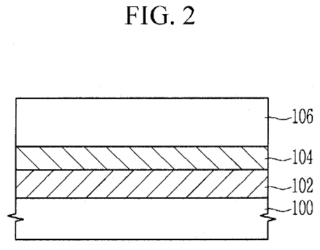

Referring to FIG. 2, the photoresist layer 106 is formed by coating the semiconductor resist composition on the resist underlayer 104. In some embodiments, the photoresist layer 106 is obtained by coating the semiconductor resist composition on the thin layer 102 formed on the substrate 100 and then, curing it through a heat treatment.

For example, the formation of a pattern by using the semiconductor resist composition may include coating the semiconductor resist composition on the substrate 100 having the thin layer 102 thereon through spin coating, slit coating, inkjet printing, and/or the like and then, drying the coated composition to form the photoresist layer 106.

The semiconductor resist composition may be the same as described above, and a duplicative description thereof will not be provided.

Subsequently, a substrate 100 having the photoresist layer 106 coated thereon is subjected to a first baking process. The first baking process may be performed at about 80° C. to about 120° C.

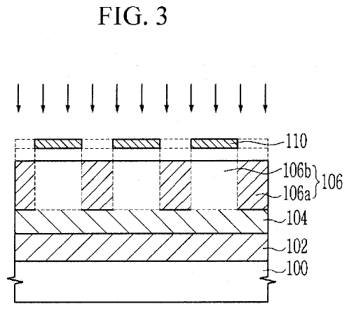

Referring to FIG. 3, the photoresist layer 106 may be selectively exposed.

For example, the act of exposure may utilize an activation radiation with light having a high energy wavelength such as EUV (Extreme UltraViolet; a wavelength of about 13.5 nm), an E-Beam (an electron beam), and/or the like, and, optionally, as well as an i-line (a wavelength of about 365 nm), a KrF (krypton fluoride) excimer laser (a wavelength of about 248 nm), an ArF (argon fluoride) excimer laser (a wavelength of about 193 nm), and/or the like.

For example, light for the exposure according to an embodiment may have a short wavelength ranging from about 5 nm to about 150 nm and a high energy wavelength, for example, EUV (Extreme UltraViolet; a wavelength of about 13.5 nm), an E-Beam (an electron beam), and/or the like.

An exposed region 106a of the photoresist layer 106 has different solubility from that of a non-exposed region 106b of the photoresist layer 106, as a carboxyl group or a hydroxy group of the organometallic compound form a polymer by a dehydration condensation reaction as described above.

Subsequently, the substrate 100 is subjected to a second baking process. The second baking process may be performed at a temperature of about 90° C. to about 200° C. The exposed region 106a of the photoresist layer 106 then becomes substantially indissoluble in a developing solution due to the second baking process.

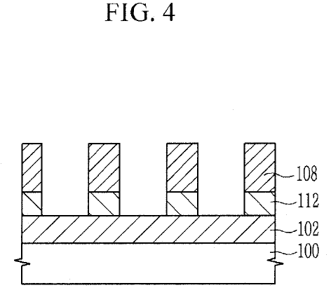

In FIG. 4, the non-exposed region 106b of the photoresist layer is dissolved and removed using the developing solution to form a photoresist pattern 108. Specifically, the non-exposed region 106b of the photoresist layer is dissolved and removed by using an organic solvent (such as ethyl lactate and/or the like) to complete the photoresist pattern 108 corresponding to the negative tone image.

As described above, a developing solution used in a method of forming patterns according to an embodiment may be an organic solvent. Non-limiting examples of the organic solvent used in the method of forming patterns according to an embodiment may include for example ketones (such as cyclohexanone, methylethylketone, acetone, 2-heptanone, and/or the like), alcohols (such as 4-methyl-2-propanol, 1-butanol, isopropanol, 1-propanol, methanol, and/or the like), esters (such as propylene glycol monomethyl ester acetate, ethyl acetate, ethyl lactate, n-butyl acetate, butyrolactone, and/or the like), aromatic compounds (such as benzene, xylene, toluene, and/or the like), and combinations thereof.

However, the photoresist pattern according to an embodiment is not necessarily limited to the negative tone image but may be formed to have a positive tone image. For example, a developing agent used for forming the positive tone image may be a quaternary ammonium hydroxide composition such as tetraethylammonium hydroxide, tetrapropylammonium hydroxide, tetrabutylammonium hydroxide, or a combination thereof.

As described above, when the activation radiation is performed by using light having a high energy wavelength such as EUV (Extreme UltraViolet; a wavelength of about 13.5 nm), an E-Beam (an electron beam), and/or the like, as well as a short wavelength such as an i-line (a wavelength of about 365 nm), a KrF excimer laser (a wavelength of about 248 nm), an ArF excimer laser (a wavelength of about 193 nm), and/or the like, the photoresist pattern 108 may have a width of about 5 nm to about 100 nm. For example, the photoresist pattern 108 may have a width of about 5 nm to about 90 nm, about 5 nm to about 80 nm, about 5 nm to about 70 nm, about 5 nm to about 60 nm, about 10 nm to about 50 nm, about 10 nm to about 40 nm, about 10 nm to about 30 nm, or about 10 nm to about 20 nm, without limitation.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

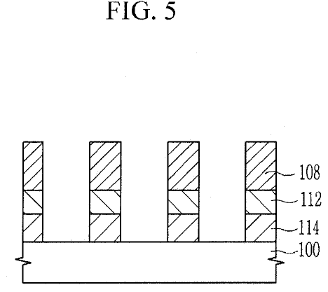

Referring to FIG. 5, the photoresist pattern 108 is applied as an etching mask to etch the exposed thin layer 102. As a result, the thin layer (e.g., thin film) is formed with a thin layer pattern 114.

The etching of the thin layer 102 to form the thin layer pattern 114 may be, for example, dry etching using an etching gas and the etching gas may be, for example, CHF₃, CF₄, Cl₂, BCl₃ or a mixed gas thereof.

In the exposure process, the thin layer pattern 114 formed by using the photoresist pattern 108 formed through the exposure process performed by using an EUV light source, for example, may have a width corresponding to that of the photoresist pattern 108. For example, the thin layer pattern 114 may have a width of about 5 nm to about 100 nm which is equal to that of the photoresist pattern 108. For example, the thin layer pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 10 nm to about 50 nm, about 10 nm to about 40 nm, about 10 nm to about 30 nm, or about 10 nm to about 20 nm, and in some embodiments, less than or equal to about 20 nm, and may correspond to the width of the photoresist pattern 108.

Hereinafter, the present invention is described in more detail through Examples regarding preparation of the semiconductor resist composition including the organometallic compound of the present embodiments. However, the present invention is not limited by the following Examples.

### Synthesis Example 1

62 mL of a BnMgCl (2.0 M in tetrahydrofuran, 125 mmol) solution was put in a 250 mL round-bottomed flask, and 31 g of (nBu)₃SnCl (95 mmol) dissolved in anhydrous tetrahydrofuran was slowly added thereto. Subsequently, the mixture was refluxed at 80° C. for 4 hours and cooled down to 10° C. Then, a 1 M HCl solution was used to complete the reaction, Mg remaining therein was filtered, and diethyl ether was used for an extraction (3×200 mL) to separate an organic layer therefrom. Subsequently, magnesium sulfate (MgSO₄) was used to remove moisture from the organic layer, and a solvent was evaporated therefrom to obtain a colorless liquid Product 1 of (nBu)₃SnBn (20 g, a yield: 85%).

Then, 22 g of SnCl₄ (84 mmol) was put in a 100 mL round-bottomed flask at −30° C. under a N₂ condition, 32 g of Product 1 was slowly added thereto in a dropwise fashion, and the mixture was heated up to room temperature and stirred for 1 hour. When the reaction was complete, the solution was dissolved in 50 mL of acetonitrile, 50 mL of pentane was five times used for an extraction, a byproduct was removed therefrom, and the rest of the solution was distilled at 110° C. under a condition of 0.5 mm Hg to obtain Product 2 (BnSnCl₃) (12 g, a yield: 45%).

Subsequently, a 0.5 N NaOH solution (133 mL) was prepared in a 250 mL round-bottomed flask, and Product 2 (7 g) was slowly added thereto, while stirred. After one hour, a product therein was filtered, washed with distilled water, and vacuum-dried to obtain an organometallic compound including a structural unit represented by Chemical Formula 7 according to Synthesis Example 1 (4.5 g, a yield: 80%):

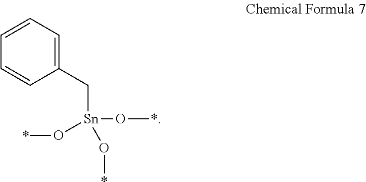

### Synthesis Example 2

An organometallic compound including a structural unit represented by Chemical Formula 8 according to Synthesis Example 2 was obtained according to the same (or substantially the same) synthesis method as Synthesis Example 1, except for using a (2-naphthalenylmethyl) magnesium bromide solution instead of the BnMgCl solution.

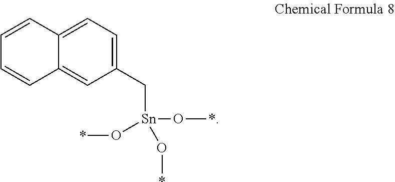

### Comparative Synthesis Example 1

An organometallic compound including a structural unit represented by Chemical Formula A according to Comparative Synthesis Example 1 was obtained according to the same (or substantially the same) synthesis method as Synthesis Example 1, except for using a (cyclohexylmethyl) magnesium bromide solution instead of the BnMgCl solution.

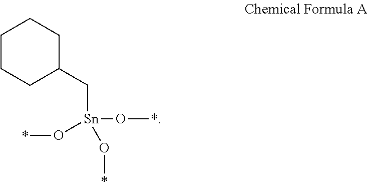

### Comparative Synthesis Example 2

A 0.5 N NaOH solution (300 mL) was prepared in a 250 mL round-bottomed flask, and 14 g of butyltin trichloride was added thereto, while slowly stirred. After one hour, a product therein was filtered, washed with distilled water, and vacuum-dried to obtain an organometallic compound including a structural unit represented by Chemical Formula B (11 g, a yield: 80%):

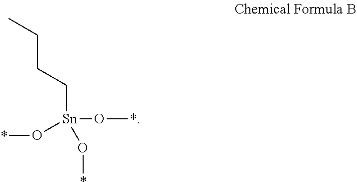

### Examples 1 and 2

Each organometallic compound according to Synthesis Examples 1 and 2 was dissolved at a concentration of 1.6 wt % in ethyl lactate, and the solution was filtered with a 0.1 μm PTFE syringe filter to prepare each semiconductor resist composition.

A 4 inch-disk silicon wafer having a native-oxide surface was used as a substrate for depositing a thin layer film, and the substrate was pretreated for 10 minutes under a UV ozone cleaning system. Then, the semiconductor resist compositions according to Examples 1 and 2 were respectively spin-coated at 1500 rpm for 30 seconds, baked (after applying the compositions, post-apply baked (PAB)) at 120° C. on a hot plate for 120 seconds to form each thin layer.

After the coating and baking, thicknesses of the films were measured through ellipsometry to be about 25 nm for each film.

### Comparative Examples 1 and 2

Each semiconductor resist composition was prepared by respectively dissolving the compounds according to Comparative Synthesis Examples 1 and 2 at a concentration of 1.6 wt % in ethyl lactate, and each solution was filtered with a 0.1 μm PTFE syringe filter.

Subsequently, the semiconductor resist compositions according to Comparative Examples 1 and 2 were respectively used to form thin layers on a substrate using the same process as in the Examples.

After the coating and baking, thicknesses of each film were measured through ellipsometry to be about 25 nm for each film.

### Evaluation 1

A linear array of 50 disk pads each having a diameter of 500 μm was transferred into a wafer coated with the respective resist composition of Examples 1 and 2 and Comparative Examples 1 and 2 by using EUV ray (Lawrence Berkeley National Laboratory Micro Exposure Tool, MET). Exposure times of the pads were adjusted to apply an increased EUV dose to each pad.

Subsequently, the exposed films were respectively baked (post-exposure baked (PEB)) on a hotplate at 150° C. for 120 seconds. The baked films were dipped in a developing solution (2-heptanone) for 30 seconds, and washed with distilled water to form a negative tone image, that is, to remove a non-exposed coating region. Finally, the resultant was baked on a 150° C. hot plate for 2 minutes to complete the process.

A residual resist thickness of the exposed pads was measured by an ellipsometer. The residual thickness was measured depending on each exposure dose and calculated therewith as a function to obtain Dg (an energy level where a development was complete) and a contrast, and the results are shown in Table 1.

Additionally, solubility and storage stability of each semiconductor resist composition according to Examples 1 and 2 and Comparative Examples 1 and 2 were evaluated, and the results are shown in Table 1.

### Solubility

The solubility of each semiconductor resist composition in an organic solvent based on a weight ratio of ethyl lactate was evaluated, and the results were denoted as follows:

o: dissolved in greater than or equal to 3 wt % of ethyl lactate;

Δ: dissolved in greater than or equal to 1 wt % and less than 3 wt % of ethyl lactate;

X: dissolved in less than 1 wt % of ethyl lactate.

### Storage Stability

The storage stability was evaluated based on whether or not there was an extraction (e.g., precipitation) when the compositions were allowed to stand at room temperature (0° C. to 30° C.) for a particular time. The results were denoted as follows:

o: storable for greater than or equal to 3 months;

Δ: storable for 1 week to less than 3 months;

X: storable for less than 1 week.

TABLE 1

| | Solubility | Storage stability | D_{g} (mJ/cm²) | Contrast |
|---|---|---|---|---|
| Example 1 | ◯ | ◯ | 15.0 | 16 |
| Example 2 | ◯ | ◯ | 16.3 | 15 |
| Comparative | Δ | ◯ | 26.1 | 10 |
| Example 1 | | | | |
| Comparative | X | Δ | 24.3 | 8 |
| Example 2 | | | | |

Referring to Table 1, each semiconductor resist composition according to Examples 1 and 2 showed excellent solubility and storage stability compared with those of Comparative Examples, and a pattern formed using the semiconductor resist compositions according to Examples 1 and 2 showed excellent sensitivity and contrast compared with those of Comparative Examples. Accordingly, Examples 1 and 2 in which carbon bonded with a central metal atom formed a benzylic bond with a condensed polycyclic aryl group showed excellent sensitivity and contrast through low bonding dissociation energy, as compared with the compositions of the Comparative Examples in which carbon bonded with a central metal atom was combined with hydrogen and an aliphatic cyclic hydrocarbon group or an aliphatic linear hydrocarbon group.

### Evaluation 2

The linear array of 50 disk pads each having a diameter of 500 μm was transferred on a wafer coated with the respective resist composition to have a pattern having a line of about 20 nm in width and about 40 nm in pitch, by using EUV ray (Lawrence Berkeley National Laboratory Micro Exposure Tool, MET, a wavelength radiation: 13.5 nm, a dipole lamp, the number of opening: 0.3).

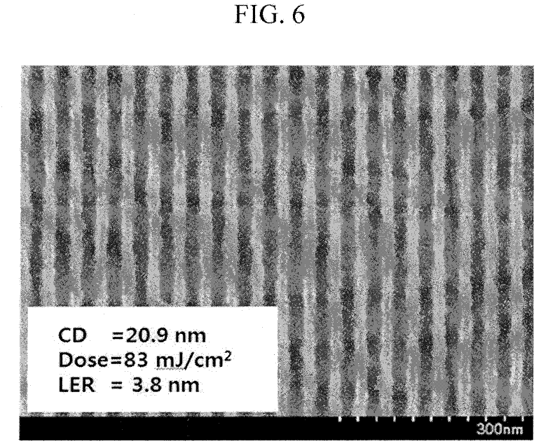

Subsequently, after forming a negative image through the same process as the one used in Evaluation 1 and completing the process, the developed negative image was measured with a scanning electron microscope (SEM), and the results are shown in FIG. 6. FIG. 6 shows results of Example 1 (using the compound of Chemical Formula 7). In FIG. 6, “CD” refers to line width.

Referring to FIG. 6, a photoresist pattern was well formed without a collapse and satisfied a desired line and space.

As used herein, expressions such as “at least one of,” “one of,” and “selected from,” when preceding a list of elements, modify the entire list of elements and do not modify the individual elements of the list. Further, the use of “may” when describing embodiments of the present invention refers to “one or more embodiments of the present invention.”

As used herein, the terms “use,” “using,” and “used” may be considered synonymous with the terms “utilize,” “utilizing,” and “utilized,” respectively.

In addition, the terms “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain example embodiments of the present invention have been described and illustrated, however, it should be apparent to a person with ordinary skill in the art that the present invention is not limited to the example embodiment as described, and may be variously modified and transformed without departing from the spirit and scope of the present invention. Accordingly, the modified or transformed example embodiments may be understood from the technical ideas and aspects of the present invention, and the modified example embodiments are within the scope of the appended the claims of the present invention and equivalents thereof.

What is claimed is:

1. A semiconductor resist composition comprising:
an organometallic compound comprising a structural unit represented by Chemical Formula 1, and
a solvent: 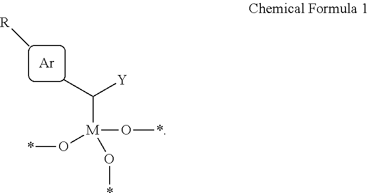
wherein, in Chemical Formula 1,
M is selected from indium (In), tin (Sn), antimony (Sb), tellurium (Te), thallium (TI), lead (Pb), bismuth (Bi), and polonium (Po),
Ar is a substituted or unsubstituted C6 to C30 aromatic ring group, a substituted or unsubstituted C4 to C30 heteroaromatic ring group, or a combination thereof,
R is selected from hydrogen, deuterium, a halogen, a substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),
R^{a} to R^{c} are each independently selected from hydrogen, deuterium, a substituted or unsubstituted C1 to C20 alkyl group, a substituted or unsubstituted C3 to C20 cycloalkyl group, and a substituted or unsubstituted C6 to C30 aryl group,
adjacent R's are optionally fused to form a ring,
Y is selected from hydrogen, deuterium, a halogen, a substituted or unsubstituted C1 to C20 alkyl group, a substituted or unsubstituted C3 to C20 cycloalkyl group, and a substituted or unsubstituted C6 to C30 aryl group, and
“*” is a linking point.

2. The semiconductor resist composition of claim 1, wherein M is selected from indium (In), tin (Sn), and antimony (Sb).

3. The semiconductor resist composition of claim 1, wherein the aromatic ring group and the heteroaromatic ring group in Ar each independently have 1 to 10 rings.

4. The semiconductor resist composition of claim 1, wherein Ar is represented by Chemical Formula 1-1: 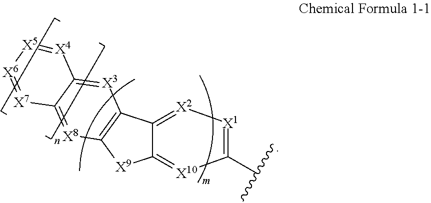
wherein, in Chemical Formula 1-1,
X¹ to X⁸ and X¹⁰ are each independently —C(R^{d})(R^{e})— or —N(R^{f})—,
X⁹ is selected from —O—, —S—, and —C(R^{g})(R^{h})—,
R^{d}, R^{e}, R^{f}, R^{g}, and R^{h} are each independently selected from hydrogen, deuterium, a substituted or unsubstituted C1 to C20 alkyl group, a substituted or unsubstituted C3 to C20 cycloalkyl group, and a substituted or unsubstituted C6 to C30 aryl group,
adjacent R^{d}, R^{e}, R^{f}, R^{g}, and R^{h} are optionally fused to form a ring, and
n and m are each independently an integer ranging from 0 to 10.

5. The semiconductor resist composition of claim 1, wherein the structural unit represented by Chemical Formula 1 is represented by Chemical Formula 2: 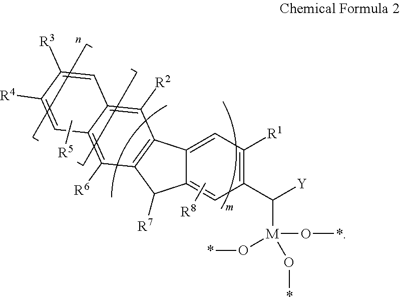
wherein, in Chemical Formula 2,
M is selected from indium (In), tin (Sn), and antimony (Sb),
R¹ to R⁸ are each independently selected from hydrogen, deuterium, a halogen, a substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),
R^{a} to R^{c} are each independently selected from hydrogen, deuterium, a substituted or unsubstituted C1 to C20 alkyl group, a substituted or unsubstituted C3 to C20 cycloalkyl group, and a substituted or unsubstituted C6 to C30 aryl group,
adjacent R¹ to R⁸ are optionally fused to form a ring,
Y is selected from hydrogen, deuterium, a halogen, a substituted or unsubstituted substituted or unsubstituted C1 to C20 alkyl group, a substituted or unsubstituted C3 to C20 cycloalkyl group, and a substituted or unsubstituted C6 to C30 aryl group, and
“*” is a linking point.

6. The semiconductor resist composition of claim 1, wherein Ar comprises at least one of the structural units of Group I:

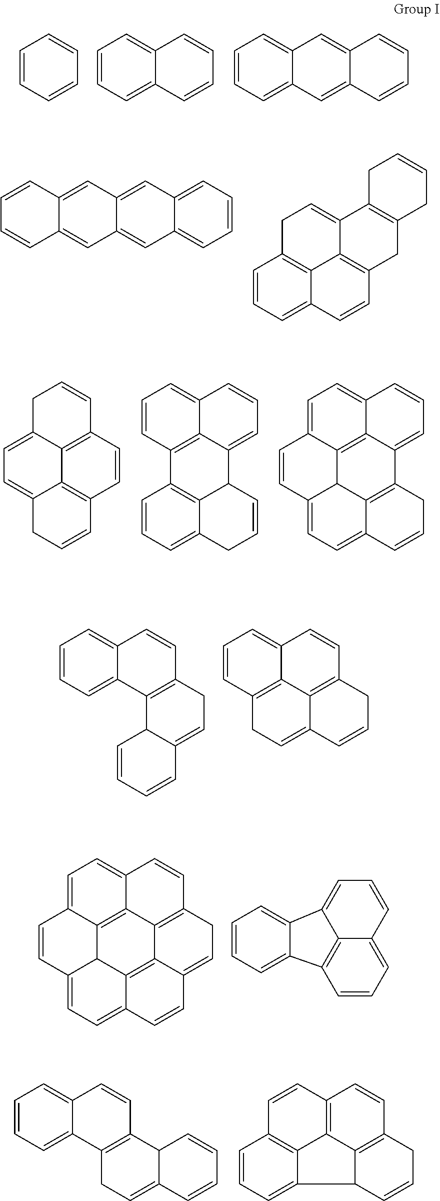

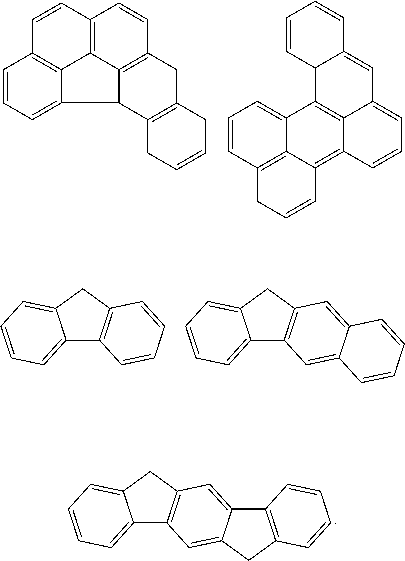

7. The semiconductor resist composition of claim 1, wherein the organometallic compound comprises at least one of structural units represented by Chemical Formulae 3 to 6: 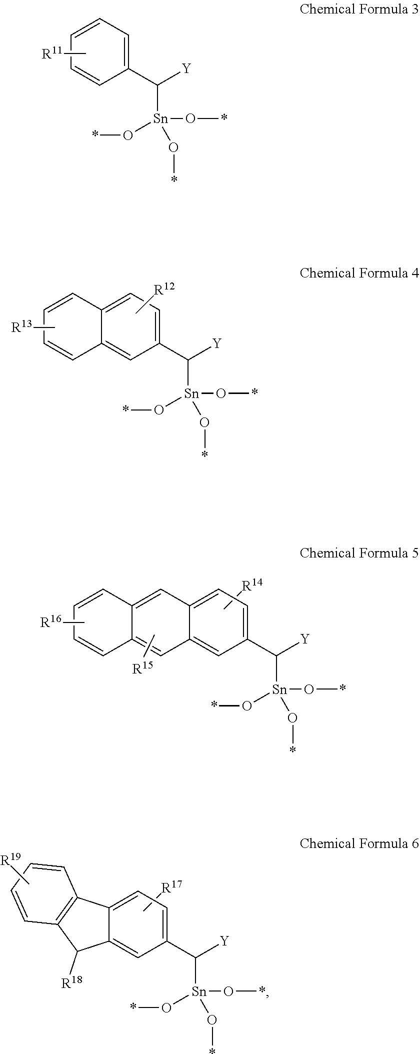
wherein, in Chemical Formula 3 to Chemical Formula 6,
R¹¹ to R¹⁹ are each independently selected from hydrogen, deuterium, a halogen, a substituted or unsubstituted C1 to C20 alkyl group, a substituted or unsubstituted C3 to C20 cycloalkyl group, a substituted or unsubstituted C6 to C30 aryl group, —N(R^{a})(R^{b}), and —O(R^{c}),
R^{a} to R^{c} are each independently selected from hydrogen, deuterium, a substituted or unsubstituted C1 to C20 alkyl group, a substituted or unsubstituted C3 to C20 cycloalkyl group, and a substituted or unsubstituted C6 to C30 aryl group,
adjacent R¹¹ to R¹⁹ are optionally fused to form a ring,
Y is selected from hydrogen, deuterium, a halogen, a substituted or unsubstituted substituted or unsubstituted C1 to C20 alkyl group, a substituted or unsubstituted C3 to C20 cycloalkyl group, and a substituted or unsubstituted C6 to C30 aryl group, and
“*” is a linking point.

8. The semiconductor resist composition of claim 1, wherein the composition further comprises an additive of a photoacid generator, a binder resin, a photopolymerizable monomer, a photopolymerization initiator, a surfactant, a cross-linking agent, a leveling agent, or a combination thereof.

9. The semiconductor resist composition of claim 8, wherein the photoacid generator comprises a diazosulfone-based compound or a triphenylsulfone-based compound, and
wherein the photoacid generator is included in an amount of about 0.1 parts by weight to about 20 parts by weight based on 100 parts by weight of the semiconductor composition.

10. The semiconductor resist composition of claim 8, wherein the binder resin is a copolymer of a first ethylenic unsaturated monomer and a second ethylenic unsaturated monomer copolymerizable with the first ethylenic unsaturated monomer, the binder resin comprising at least one acryl-based repeating unit, and
wherein the binder resin is included in an amount of about 1 wt % to about 20 wt % based on a total amount of semiconductor resist composition.

11. The semiconductor resist composition of claim 8, wherein the photopolymerizable monomer is a mono-functional or multi-functional ester of (meth)acrylic acid comprising at least one ethylenic unsaturated double bond, and
wherein the photopolymerizable monomer is included in an amount of about 1 wt % to about 20 wt % based on a total amount of semiconductor resist composition.

12. A method of forming patterns, the method comprising:
coating the semiconductor resist composition of claim 1 on an etching subject layer to form a photoresist layer;
patterning the photoresist layer to form a photoresist pattern; and
etching the etching subject layer using the photoresist pattern as an etching mask.

13. The method of claim 12, wherein the photoresist pattern is formed using light in a wavelength of about 5 nm to about 150 nm.

14. The method of claim 12, wherein the etching subject layer is provided on a substrate.

15. The method of claim 14, further comprising providing a resist underlayer between the substrate and the photoresist layer.

16. The method of claim 12, further comprising:
drying the coated semiconductor resist composition at about 80° C. to about 120° C., and
curing the patterned photoresist layer at 90° C. to about 200° C.

17. The method of claim 12, wherein the photoresist pattern has a width of about 5 nm to about 100 nm.

18. The method of claim 12, wherein the photoresist pattern is formed using an extreme ultraviolet (EUV) light source of a wavelength of about 13.5 nm.

19. A system of forming patterns, the system comprising:
means for coating the semiconductor resist composition of claim 1 on an etching subject layer to form a photoresist layer;
means for patterning the photoresist layer to form a photoresist pattern; and
means for etching the etching subject layer using the photoresist pattern as an etching mask.
